(19) United States
(12) Patent Application Publication
(10) Pub. No.: US 2025/0316491 A1
(43) Pub. Date: Oct. 9, 2025

(54) INTEGRATED SUBSTRATE THINNING

(71) Applicant: Applied Materials, Inc., Santa Clara, CA (US)

(72) Inventors: Benjamin Jacob Cherian, San Jose, CA (US); Devika Sarkar Grant, Valley Center, CA (US); Xiaoqun Zou, Danville, CA (US); Eric Lee Lau, Santa Clara, CA (US); Jatinder Bir Singh Randhawa, Tracy, CA (US); Bocheng Cao, San Jose, CA (US); Palash Gajjar, Santa Clara, CA (US)

(21) Appl. No.: 19/171,657

(22) Filed: Apr. 7, 2025

Related U.S. Application Data
(60) Provisional application No. 63/631,388, filed on Apr. 8, 2024.

(51) Int. Cl. H01L 21/3105; G06N 5/022; H01L 21/306

(52) U.S. Cl. CPC H01L 21/31053; G06N 5/022; H01L 21/30604

(57) ABSTRACT

A method includes identifying a substrate thickness map of a substrate thinned via one or more chemical mechanical planarization (CMP) operations. The method further includes causing, based on the substrate thickness map, additional thinning of the substrate via etching of the substrate.

### RELATED APPLICATIONS

This application claims the benefit of U.S. Provisional Patent Application No. 63/631,388 filed Apr. 8, 2024, the contents of which is incorporated by reference in its entirety herein.

### TECHNICAL FIELD

The present disclosure relates to operations in manufacturing systems, such as substrate processing systems, and in particular to integrated substrate thinning in substrate processing systems.

### BACKGROUND

Products are produced by performing one or more manufacturing processes using manufacturing systems. For example, substrate processing systems are used to process substrates.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, a method includes: identifying a substrate thickness map of a substrate thinned via one or more chemical mechanical planarization (CMP) operations; and causing, based on the substrate thickness map, additional thinning of the substrate via etching of the substrate.

In another aspect of the disclosure, a non-transitory machine-readable storage medium storing instructions which, when executed cause a processing device to perform operations including: identifying a substrate thickness map of a substrate thinned via one or more chemical mechanical planarization (CMP) operations; and causing, based on the substrate thickness map, additional thinning of the substrate via etching of the substrate.

In another aspect of the disclosure, a system includes memory and a processing device coupled to the memory. The processing device is to: identify a substrate thickness map of a substrate thinned via one or more chemical mechanical planarization (CMP) operations; and cause, based on the substrate thickness map, additional thinning of the substrate via etching of the substrate.

### BRIEF DESCRIPTION OF THE DRAWINGS

The present disclosure is illustrated by way of example, and not by way of limitation in the figures of the accompanying drawings.

FIG. 1 is a block diagram illustrating an exemplary system architecture, according to certain embodiments.

FIGS. 2A-B illustrate data set generators to create data sets for machine learning models, according to certain embodiments.

FIG. 3 is a block diagram illustrating determining predictive data, according to certain embodiments.

FIGS. 4A-E are flow diagrams of methods associated with integrated substrate thinning, according to certain embodiments.

FIG. 5 is a block diagram illustrating a computer system, according to certain embodiments.

### DETAILED DESCRIPTION

Described herein are technologies directed to integrated substrate thinning (e.g., an integrated approach to silicon thinning).

Products are produced by performing one or more manufacturing processes using manufacturing systems. For example, a substrate processing system is used to process substrates (e.g., wafers, semiconductors, displays, etc.).

During substrate processing, operations are performed to reduce thickness of substrates. Conventionally, there is a lot of variability in thicknesses of substrates after different operations. This causes high asymmetry of substrates. This causes substrates to malfunction, decreased yield, decreases uniformity, increases waste of materials and energy, etc.

Lack of uniformity of thickness of substrates can cause problems during subsequent substrate processing operations. Subsequent substrate processing operations of a substrate that has non-uniform thickness can cause some portions of a substrate to be completely removed (e.g., remove material all the way to the transistor, destroying some of the transistors, etc.) and other portions may have too much material.

The devices, systems, and methods disclosed herein provide solutions to these and other shortcomings of conventional systems.

In some embodiments, a processing device identifies a substrate thickness map of a substrate thinned via one or more CMP (chemical mechanical planarization or chemical mechanical polishing) operations. This may include receiving metrology data in situ during thinning of the substrate via the CMP operations and generating, based on the metrology data, the substrate thickness map of the substrate.

In some embodiments, the substrate thickness map is generated based on output of a trained machine learning model responsive to input of metrology data. The trained machine learning model may be trained with data input of historical metrology data (e.g., of historical substrates associated with performing historical CMP operations) and target data of historical substrate thickness maps (e.g., associated with the historical substrates thinned via the historical CMP operations).

In some embodiments, the processing device causes, based on the substrate thickness map, additional thinning of the substrate via etching of the substrate. In some embodiments, this includes determining, based on the substrate thickness map, temperature offsets and causing, based on the temperature offsets, microzone heating of the substrate during etching of the substrate. In some embodiments, the causing of the additional thinning includes causing, based on the substrate thickness map, adjustment of height of a process kit ring (e.g., edge ring) associated with the etching of the substrate. The additional thinning may cause the substrate to have a planarization value that is more planar than a planarization value prior to the etching of the substrate (e.g., a planarization value that is more planar than a planarization value after the CMP operations).

In some embodiments, the causing of the additional thinning is based on output of a trained machine learning model responsive to input of the substrate thickness map. The trained machine learning model may be trained with data input of historical substrate thickness maps (e.g., associated with historical substrates thinned via the historical CMP operations) and target output of historical performance data (e.g., associated with the historical substrates thinned via the historical CMP operations).

Aspects of the present disclosure result in technological advantages. The present disclosure may cause less variability in thickness of substrates and higher symmetry of substrates compared to conventional systems. This may allow the present disclosure to produce substrates that have less malfunctioning, have increased yield, have increased uniformity, have decrease waste of materials and energy, etc. compared to conventional systems. The present disclosure may have increased uniformity of thickness that causes subsequent substrate processing operations to have less problems compared to conventional solutions. This may allow the present disclosure to more evenly remove thickness of the substrate (e.g., not remove material all the way to the transistor, not destroy transistors, not leave too much material, etc.) compared to conventional systems.

Although some embodiments of the present disclosure are described in relation to causing additional thinning via etching based on a substrate thickness map responsive to CMP operations, the present disclosure, in some embodiments, is directed to performing any subsequent operations (e.g., one or more subsequent thinning operation) based on metrology data after performing preliminary operations (e.g., one or more preliminary thinning operations).

Although some embodiments of the present disclosure are described in relation to thinning a silicon layer of a substrate, the present disclosure, in some embodiments, is directed to thinning other materials. For example, a few microns of oxide may be removed, the oxide may be polished, metrology data may be determined from center to edge of the oxide, a thickness map may be generated, and a dielectric etch tool may fix the asymmetry of the oxide layer based on the thickness map.

As used herein, the term “produce” can refer to producing a final version of a product (e.g., completely processed substrate) or an intermediary version of a product (e.g., partially processed substrate). As used herein, the producing substrates can refer to processing substrates via performance of one or more substrate processing operations.

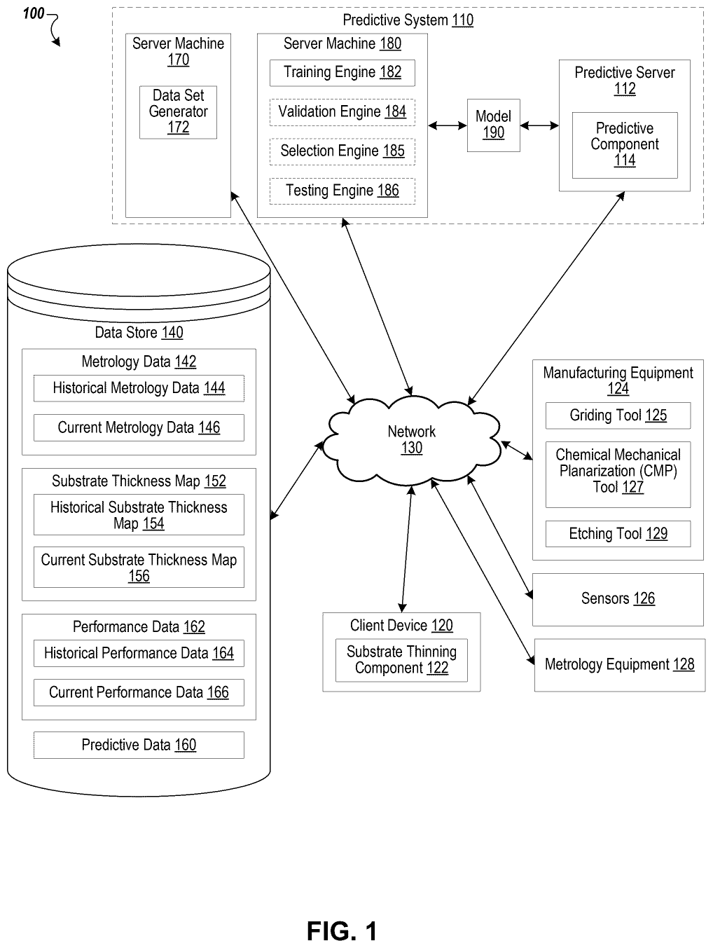

FIG. 1 is a block diagram illustrating an exemplary system 100 (exemplary system architecture), according to certain embodiments. The system 100 includes a client device 120, manufacturing equipment 124, sensors 126, metrology equipment 128, a predictive server 112, and a data store 140. In some embodiments, the predictive server 112 is part of a predictive system 110. In some embodiments, the predictive system 110 further includes server machines 170 and 180.

In some embodiments, one or more of the client device 120, manufacturing equipment 124, sensors 126, metrology equipment 128, predictive server 112, data store 140, server machine 170, and/or server machine 180 are coupled to each other via a network 130 for generating predictive data 160 to perform integrated substrate thinning. In some embodiments, network 130 is a public network that provides client device 120 with access to the predictive server 112, data store 140, and other publicly available computing devices. In some embodiments, network 130 is a private network that provides client device 120 access to manufacturing equipment 124, sensors 126, metrology equipment 128, data store 140, and other privately available computing devices. In some embodiments, network 130 includes one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

In some embodiments, the client device 120 includes a computing device such as Personal Computers (PCs), laptops, mobile phones, smart phones, tablet computers, netbook computers, etc. In some embodiments, the client device 120 includes a substrate thinning component 122. In some embodiments, the substrate thinning component 122 may also be included in the predictive system 110 (e.g., machine learning processing system). In some embodiments, the substrate thinning component 122 is alternatively included in the predictive system 110 (e.g., instead of being included in client device 120). Client device 120 includes an operating system that allows users to one or more of consolidate, generate, view, or edit data, provide directives to the predictive system 110 (e.g., machine learning processing system), etc.

In some embodiments, substrate thinning component 122 receives one or more of user input (e.g., via a Graphical User Interface (GUI) displayed via the client device 120), receives metrology data 142, substrate thickness map 152, and/or performance data 162. In some embodiments, the substrate thinning component 122 transmits at least a portion of the data (e.g., user input, metrology data 142, substrate thickness map 152, and/or performance data 162) to the predictive system 110, receives predictive data 160 from the predictive system 110, and causes thinning operations based on the predictive data 160. In some embodiments, the substrate thinning component 122 stores data (e.g., user input, metrology data 142, substrate thickness map 152, and/or performance data 162) in the data store 140 and the predictive server 112 retrieves data from the data store 140. In some embodiments, the predictive server 112 stores output (e.g., predictive data 160) of the trained machine learning model 190 in the data store 140 and the client device 120 retrieves the output from the data store 140. In some embodiments, the substrate thinning component 122 receives an indication of a substrate thickness map 152 (e.g., based on predictive data 160) from the predictive system 110 and causes thinning operations based on the substrate thickness map 152.

In some embodiments, the predictive data 160 is associated with predicted substrate thickness map. In some embodiments, predictive data 160 is associated with additional thinning via etching. In some embodiments, additional thinning via etching is performed based on the predictive data 160.

In some embodiments, the predictive server 112, server machine 170, and server machine 180 each include one or more computing devices such as a rackmount server, a router computer, a server computer, a personal computer, a mainframe computer, a laptop computer, a tablet computer, a desktop computer, Graphics Processing Unit (GPU), accelerator Application-Specific Integrated Circuit (ASIC) (e.g., Tensor Processing Unit (TPU)), etc.

The predictive server 112 includes a predictive component 114. In some embodiments, the predictive component 114 receives metrology data 142 and/or a substrate thickness map 152 (e.g., received from the client device 120, retrieved from the data store 140) and generates predictive data 160 associated with additional thinning via etching. In some embodiments, the predictive component 114 uses one or more trained machine learning models 190 to determine the predictive data 160 associated with additional thinning via etching. In some embodiments, trained machine learning model 190 is trained using historical data (e.g., historical metrology data 144 and historical substrate thickness map 154, historical substrate thickness map 154 and historical performance data 164).

In some embodiments, the predictive system 110 (e.g., predictive server 112, predictive component 114) generates predictive data 160 using supervised machine learning (e.g., supervised data set, historical data labeled with historical data, etc.). In some embodiments, the predictive system 110 generates predictive data 160 using semi-supervised learning (e.g., semi-supervised data set, historical data is a predictive percentage, etc.). In some embodiments, the predictive system 110 generates predictive data 160 using unsupervised machine learning (e.g., unsupervised data set, clustering, clustering based on historical data, etc.).

In some embodiments, the manufacturing equipment 124 (e.g., cluster tool) is part of a substrate processing system (e.g., integrated processing system). The manufacturing equipment 124 includes one or more of a controller, an enclosure system (e.g., substrate carrier, front opening unified pod (FOUP), auto teach FOUP, process kit enclosure system, substrate enclosure system, cassette, etc.), a side storage pod (SSP), an aligner device (e.g., aligner chamber), a factory interface (e.g., equipment front end module (EFEM)), a load lock, a transfer chamber, one or more processing chambers (e.g., multi-slot processing chambers), a robot arm (e.g., disposed in the transfer chamber, disposed in the front interface, etc.), and/or the like. The enclosure system, SSP, and load lock mount to the factory interface and a robot arm disposed in the factory interface is to transfer content (e.g., substrates, process kit rings, carriers, validation wafer, etc.) between the enclosure system, SSP, load lock, and factory interface. The aligner device is disposed in the factory interface to align the content. The load lock and the processing chambers mount to the transfer chamber and a robot arm disposed in the transfer chamber is to transfer content (e.g., substrates, process kit rings, carriers, validation wafer, etc.) between the load lock, the processing chambers, and the transfer chamber. In some embodiments, the manufacturing equipment 124 includes components of substrate processing systems. In some embodiments, the manufacturing equipment 124 includes one or more of a grinding tool 125 configured to perform one or more grinding operations to remove thickness of substrates, a CMP tool 127 configured to perform one or more CMP operations to remove thickness of substrates, and/or an etching tool 129 (e.g., microzone etching tool) configured to perform additional thinning operations via etching to remove thickness of substrates. In some embodiments, metrology data 142 is generated in situ (e.g., during performance of substrate processing operations via manufacturing equipment 124, metrology equipment 128 is located inside CMP tool 127 and/or etching tool 129). In some embodiments, metrology data 142 is generated after performance of substrate processing operations via manufacturing equipment 124.

In some embodiments, the sensors 126 provide sensor data (e.g., sensor values, such as historical sensor values and current sensor values) associated with manufacturing equipment 124. In some embodiments, the sensors 126 include one or more of a radio frequency (RF) sensor, a lift sensor, an imaging sensor (e.g., camera, image capturing device, etc.), a pressure sensor, a temperature sensor, a flow rate sensor, a spectroscopy sensor, and/or the like. In some embodiments, the sensor data used for equipment health and/or product health (e.g., product quality). In some embodiments, the sensor data is received over a period of time. In some embodiments, sensors 126 provide sensor data such as values of one or more of image data, leak rate, temperature, pressure, flow rate (e.g., gas flow), pumping efficiency, spacing (SP), High Frequency Radio Frequency (HFRF), electrical current, power, voltage, and/or the like. In some embodiments, performance data 162 includes sensor data from one or more of sensors 126.

In some embodiments, the metrology equipment 128 (e.g., imaging equipment, spectroscopy equipment, ellipsometry equipment, in-situ spectral reflectometry equipment, etc.) is used to determine metrology data (e.g., inspection data, image data, spectroscopy data, ellipsometry data, material compositional, optical, or structural data, in-situ spectral reflectometry data, etc.) corresponding to substrates produced by the manufacturing equipment 124 (e.g., substrate processing equipment). In some examples, during and/or after the manufacturing equipment 124 processes substrates, the metrology equipment 128 is used to inspect portions (e.g., layers) of the substrates. In some embodiments, the metrology equipment 128 performs scanning acoustic microscopy (SAM), ultrasonic inspection, x-ray inspection, and/or computed tomography (CT) inspection. In some examples, after the manufacturing equipment 124 performs thinning of the substrate (e.g., via grinding, via CMP, via etching) and the metrology equipment 128 is used to determine quality of the processed substrate (e.g., thicknesses of the layers, uniformity of the layers, interlayer spacing of the layer, and/or the like). In some embodiments, the metrology equipment 128 includes an image capturing device (e.g., SAM equipment, ultrasonic equipment, x-ray equipment, CT equipment, and/or the like). In some embodiments, metrology data 142 and/or performance data 162 includes metrology data from metrology equipment 128.

In some embodiments, the metrology data 142, substrate thickness map 152, and/or performance data 162 is processed by the client device 120 and/or by the predictive server 112. In some embodiments, processing of the metrology data 142, substrate thickness map 152, and/or performance data 162 includes generating features. In some embodiments, the features are a portion of the data, processed data, patterns in the data, or a combination of values from the data (e.g., ratio, etc.). In some embodiments, the metrology data 142, substrate thickness map 152, and/or performance data 162 includes features that are used by the predictive component 114 for obtaining predictive data 160.

In some embodiments, the data store 140 is memory (e.g., random access memory), a drive (e.g., a hard drive, a flash drive), a database system, or another type of component or device capable of storing data. In some embodiments, data store 140 includes multiple storage components (e.g., multiple drives or multiple databases) that span multiple computing devices (e.g., multiple server computers). In some embodiments, the data store 140 stores one or more of the metrology data 142, substrate thickness map 152, performance data 162, and/or predictive data 160.

Metrology data 142 includes historical metrology data 144 and current metrology data 146. In some embodiments, metrology data 142 may include one or more of property values of a substrate, thickness values of a substrate, etc. In some embodiments, at least a portion of the metrology data 142 is from client device 120, data store 140, and/or metrology equipment 128.

Substrate thickness map 152 includes historical substrate thickness map 154 and current substrate thickness map 156. A substrate thickness map 152 may include thickness values at different coordinates of a substrate.

Performance data 162 includes historical performance data 164 and current performance data 166. In some embodiments, the performance data 164 is associated with metrology data collected during or after the additional thinning of the substrate via etching (e.g., microzone etching) based on the substrate thickness map 152. In some embodiments, at least a portion of the performance data 162 is associated with performance of a substrate, whether property values of a substrate meet threshold values, etc. In some examples, the performance data 162 is indicative of whether a substrate is properly designed, properly produced, and/or properly functioning. In some embodiments, at least a portion of the performance data 162 is associated with a quality of substrates produced by the manufacturing equipment 124. In some embodiments, at least a portion of the performance data 162 is based on metrology data 142 from the metrology equipment 128 (e.g., historical performance data 164 includes metrology data indicating properly processed substrates, property data of substrates, yield, etc.). In some embodiments, at least a portion of the performance data 162 is based on inspection of the substrates (e.g., current performance data 166 based on actual inspection). In some embodiments, the performance data 162 includes an indication of an absolute value (e.g., data indicates missing the threshold data by a calculated value, value misses the threshold value by a calculated value) or a relative value (e.g., data indicates missing the threshold by 5%). In some embodiments, the performance data 162 is indicative of meeting a threshold amount of error (e.g., at least 5% error in production, at least 5% error in flow, at least 5% error in deformation, specification limit).

In some embodiments, the client device 120 provides performance data 162 (e.g., product data). In some examples, the client device 120 provides (e.g., based on user input) performance data 162 that indicates an abnormality in products (e.g., defective products). In some embodiments, the performance data 162 includes an amount of products that have been produced that were normal or abnormal (e.g., 98% normal products). In some embodiments, the performance data 162 indicates an amount of products that are being produced that are predicted as normal or abnormal. In some embodiments, the performance data 162 includes one or more of yield a previous batch of products, average yield, predicted yield, predicted amount of defective or non-defective product, or the like. In some examples, responsive to yield on a first batch of products being 98% (e.g., 98% of the products were normal and 2% were abnormal), the client device 120 provides performance data 162 indicating that the upcoming batch of products is to have a yield of 98%.

In some embodiments, historical data includes one or more of historical metrology data 144, historical substrate thickness map 154, and/or historical performance data 164 (e.g., at least a portion for training the machine learning model 190). Current data includes one or more of current metrology data 146, current substrate thickness map 156, and/or current performance data 166 (e.g., at least a portion to be input into the trained machine learning model 190 subsequent to training the model 190 using the historical data). In some embodiments, the current data is used for retraining the trained machine learning model 190.

In some embodiments, the predictive data 160 is to be used to determine substrate thickness map 152 and/or to perform additional thinning via etching.

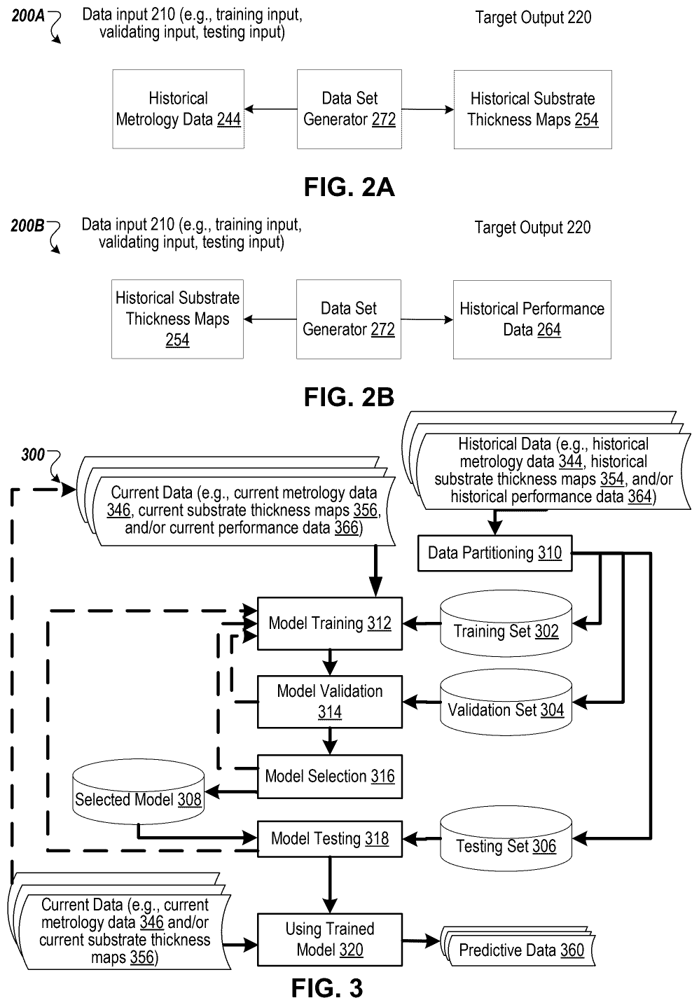

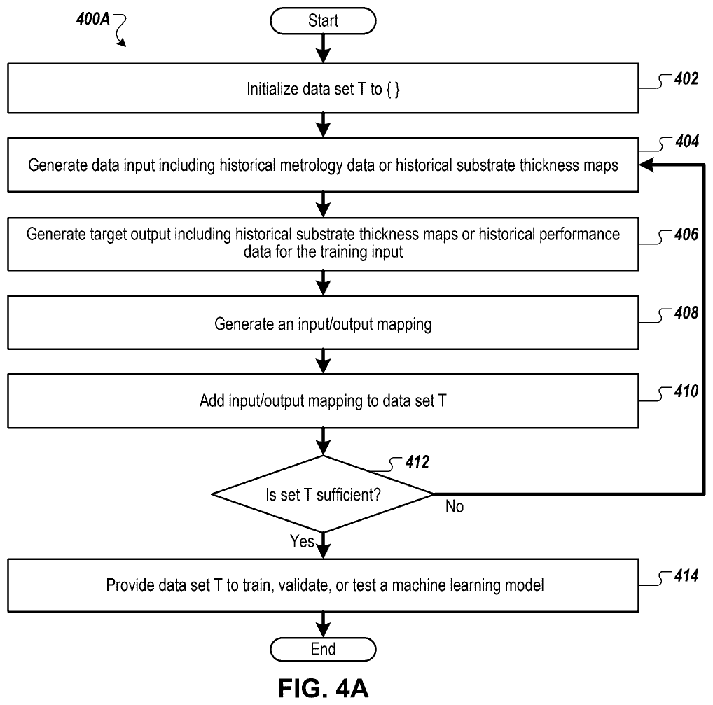

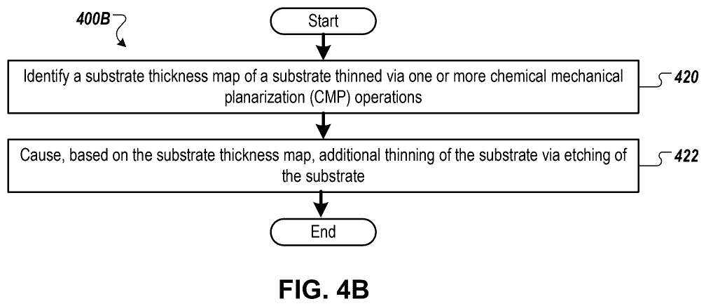

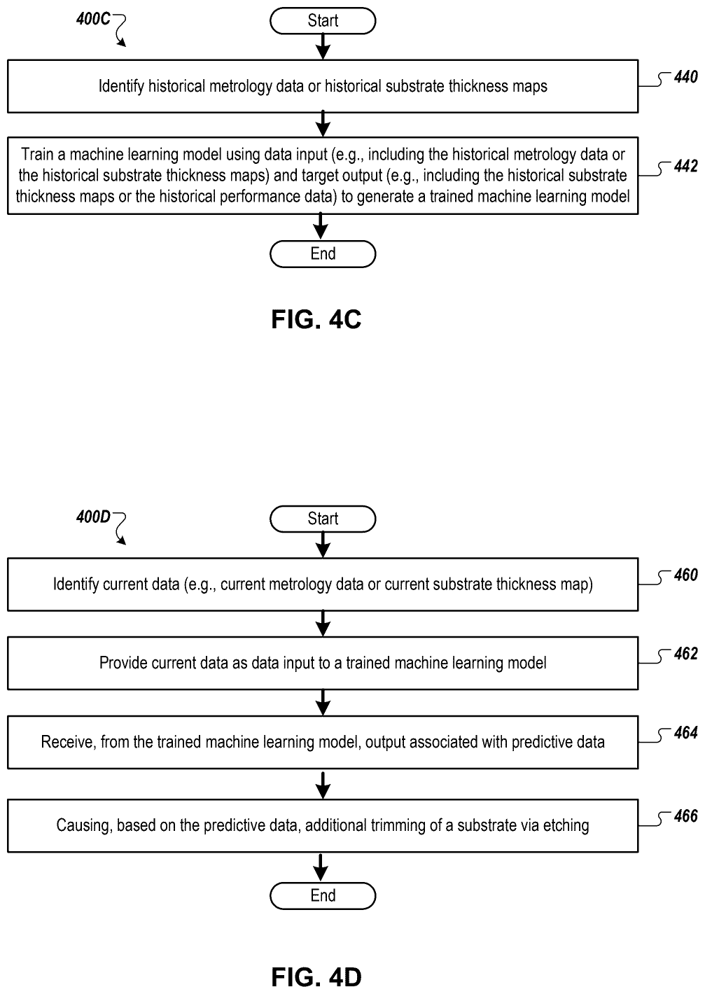

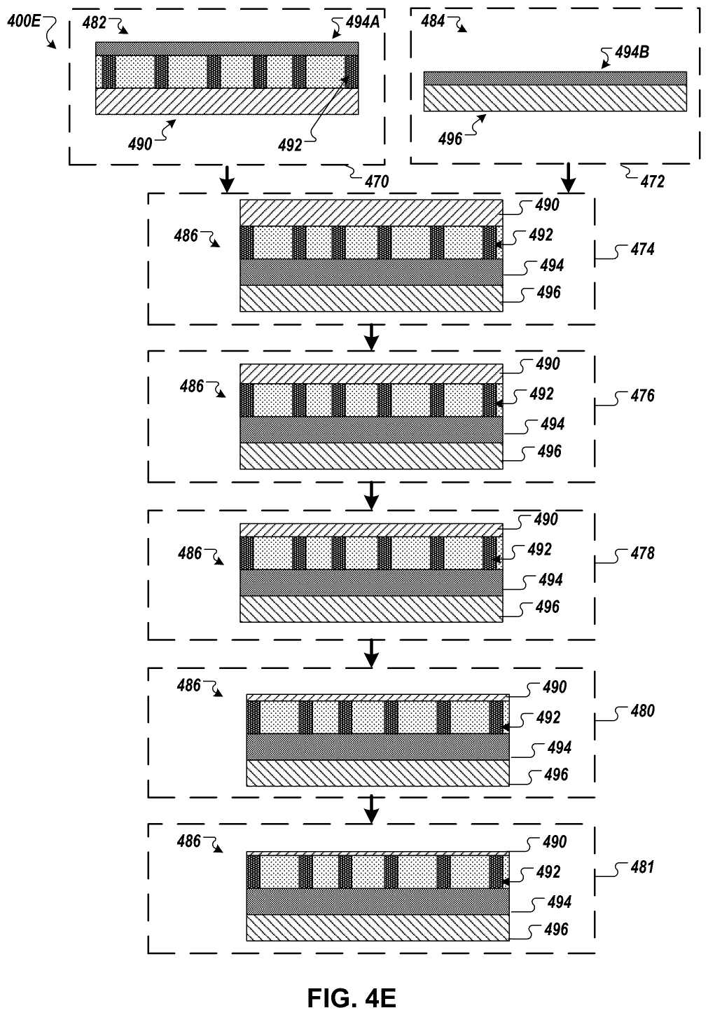

In some embodiments, predictive system 110 further includes server machine 170 and server machine 180. Server machine 170 includes a data set generator 172 that is capable of generating data sets (e.g., a set of data inputs and a set of target outputs) to train, validate, and/or test a machine learning model(s) 190. The data set generator 172 has functions of data gathering, compilation, reduction, and/or partitioning to put the data in a form for machine learning. In some embodiments (e.g., for small datasets), partitioning (e.g., explicit partitioning) for post-training validation is not used. Repeated cross-validation (e.g., 5-fold cross-validation, leave-one-out-cross-validation) may be used during training where a given dataset is in-effect repeatedly partitioned into different training and validation sets during training. A model (e.g., the best model, the model with the highest accuracy, etc.) is chosen from vectors of models over automatically separated combinatoric subsets. In some embodiments, the data set generator 172 may explicitly partition the historical data into a training set (e.g., sixty percent of the historical data), a validating set (e.g., twenty percent of the historical data), and a testing set (e.g., twenty percent of the historical data). In this embodiment, some operations of data set generator 172 are described in detail below with respect to FIGS. 2 and 4A. In some embodiments, the predictive system 110 (e.g., via predictive component 114) generates multiple sets of features (e.g., training features). In some examples a first set of features corresponds to a first set of types of metrology data 142, substrate thickness map 152, and/or performance data 162 (e.g., first types of metrology data, associated with a first set of sensors, first combination of values, first patterns in the values) that correspond to each of the data sets (e.g., training set, validation set, and testing set) and a second set of features correspond to a second set of types of metrology data 142, substrate thickness map 152, and/or performance data 162 (e.g., second types of metrology data, associated with a second set of sensors different from the first set of sensors, second combination of values different from the first combination, second patterns different from the first patterns) that correspond to each of the data sets.

Server machine 180 includes a training engine 182, a validation engine 184, selection engine 185, and/or a testing engine 186. In some embodiments, an engine (e.g., training engine 182, a validation engine 184, selection engine 185, and a testing engine 186) refers to hardware (e.g., circuitry, dedicated logic, programmable logic, microcode, processing device, etc.), software (such as instructions run on a processing device, a general purpose computer system, or a dedicated machine), firmware, microcode, or a combination thereof. The training engine 182 is capable of training a machine learning model 190 using one or more sets of features associated with the training set from data set generator 172. In some embodiments, the training engine 182 generates multiple trained machine learning models 190, where each trained machine learning model 190 corresponds to a distinct set of parameters of the training set (e.g., metrology data 142 and/or substrate thickness map 152) and corresponding responses (e.g., substrate thickness map 152 and/or performance data 162). In some embodiments, multiple models are trained on the same parameters with distinct targets for the purpose of modeling multiple effects. In some examples, a first trained machine learning model was trained using historical data for all operations (e.g., operations 1-5), a second trained machine learning model was trained using a first subset of the historical data (e.g., operations 1, 2, and 4), and a third trained machine learning model was trained using a second subset of the historical data (e.g., operations 1, 3, 4, and 5) that partially overlaps the first subset of features.

The validation engine 184 is capable of validating a trained machine learning model 190 using a corresponding set of features of the validation set from data set generator 172. For example, a first trained machine learning model 190 that was trained using a first set of features of the training set is validated using the first set of features of the validation set. The validation engine 184 determines an accuracy of each of the trained machine learning models 190 based on the corresponding sets of features of the validation set. The validation engine 184 evaluates and flags (e.g., to be discarded) trained machine learning models 190 that have an accuracy that does not meet a threshold accuracy. In some embodiments, the selection engine 185 is capable of selecting one or more trained machine learning models 190 that have an accuracy that meets a threshold accuracy. In some embodiments, the selection engine 185 is capable of selecting the trained machine learning model 190 that has the highest accuracy of the trained machine learning models 190.

The testing engine 186 is capable of testing a trained machine learning model 190 using a corresponding set of features of a testing set from data set generator 172. For example, a first trained machine learning model 190 that was trained using a first set of features of the training set is tested using the first set of features of the testing set. The testing engine 186 determines a trained machine learning model 190 that has the highest accuracy of all of the trained machine learning models based on the testing sets.

In some embodiments, the machine learning model 190 (e.g., used for classification) refers to a model artifact that is created by the training engine 182 using a training set that includes data inputs and corresponding target outputs (e.g., correctly classifies a condition or ordinal level for respective training inputs). Patterns in the data sets can be found that map the data input to the target output (the correct classification or level), and the machine learning model 190 is provided mappings that captures these patterns. In some embodiments, the machine learning model 190 uses one or more of Gaussian Process Regression (GPR), Gaussian Process Classification (GPC), Bayesian Neural Networks, Neural Network Gaussian Processes, Deep Belief Network, Gaussian Mixture Model, or other Probabilistic Learning methods. Non probabilistic methods may also be used including one or more of Support Vector Machine (SVM), Radial Basis Function (RBF), clustering, Nearest Neighbor algorithm (k-NN), linear regression, random forest, neural network (e.g., artificial neural network), etc. In some embodiments, the machine learning model 190 is a multi-variate analysis (MVA) regression model.

Predictive component 114 provides current metrology data 146 (e.g., as input) to the trained machine learning model 190 and runs the trained machine learning model 190 (e.g., on the input to obtain one or more outputs). The predictive component 114 is capable of determining (e.g., extracting) predictive data 160 from the trained machine learning model 190 and determines (e.g., extracts) uncertainty data that indicates a level of credibility that the predictive data 160 corresponds to current data. In some embodiments, the predictive component 114 or substrate thinning component 122 use the uncertainty data (e.g., uncertainty function or acquisition function derived from uncertainty function) to decide whether to use the predictive data 160 to perform additional thinning via etching or whether to further train the model 190.

For purpose of illustration, rather than limitation, aspects of the disclosure describe the training of one or more machine learning models 190 using historical data and providing current data into the one or more trained probabilistic machine learning models 190 to determine predictive data 160. In other implementations, a heuristic model or rule-based model is used to determine predictive data 160 (e.g., without using a trained machine learning model). In other implementations non-probabilistic machine learning models may be used. Predictive component 114 monitors historical data. In some embodiments, any of the information described with respect to data inputs 210 of FIGS. 2A-B are monitored or otherwise used in the heuristic or rule-based model.

In some embodiments, the functions of client device 120, predictive server 112, server machine 170, and server machine 180 are be provided by a fewer number of machines. For example, in some embodiments, server machines 170 and 180 are integrated into a single machine, while in some other embodiments, server machine 170, server machine 180, and predictive server 112 are integrated into a single machine. In some embodiments, client device 120 and predictive server 112 are integrated into a single machine.

In general, functions described in one embodiment as being performed by client device 120, predictive server 112, server machine 170, and server machine 180 can also be performed on predictive server 112 in other embodiments, if appropriate. In addition, the functionality attributed to a particular component can be performed by different or multiple components operating together. For example, in some embodiments, the predictive server 112 determines performance of additional thinning via etching based on the predictive data 160. In another example, client device 120 determines the predictive data 160 based on data received from the trained machine learning model.

In addition, the functions of a particular component can be performed by different or multiple components operating together. In some embodiments, one or more of the predictive server 112, server machine 170, or server machine 180 are accessed as a service provided to other systems or devices through appropriate application programming interfaces (API).

In some embodiments, a “user” is represented as a single individual. However, other embodiments of the disclosure encompass a “user” being an entity controlled by a plurality of users and/or an automated source. In some examples, a set of individual users federated as a group of administrators is considered a “user.”

Although embodiments of the disclosure are discussed in terms of determining predictive data 160 to perform additional thinning via etching in manufacturing facilities (e.g., substrate processing facilities), in some embodiments, the disclosure can also be generally applied to performing operations. Embodiments can be generally applied to performing subsequent operations based on data.

FIGS. 2A-B illustrate data set generators 272 (e.g., data set generator 172 of FIG. 1) to create data sets for machine learning models (e.g., model 190 of FIG. 1), according to certain embodiments. In some embodiments, data set generator 272 is part of server machine 170 of FIG. 1. The data sets generated by data set generator 272 of FIGS. 2A-B may be used to train a machine learning model (e.g., see FIG. 4C) to perform additional thinning via etching (e.g., see FIG. 4D).

Systems 200A-B of FIGS. 2A-B illustrate data set generators 272, data inputs 210, and target output 220 (e.g., target data). Data set generator 272 (e.g., data set generator 172 of FIG. 1) creates data sets for a machine learning model (e.g., model 190 of FIG. 1). Data set generator 272 creates data sets using historical data. Referring to FIG. 2A, data set generator 272 may create a data set using historical metrology data 244 (e.g., historical metrology data 144 of FIG. 1) and historical substrate thickness maps 254 (e.g., historical substrate thickness maps 154 of FIG. 1). Referring to FIG. 2B, data set generator 272 may generate a data set using historical substrate thickness maps 254 (e.g., historical substrate thickness maps 154 of FIG. 1) and historical performance data 264 (e.g., historical performance data 164 of FIG. 1).

In some embodiments, data set generator 272 generates a data set (e.g., training set, validating set, testing set) that includes one or more data inputs 210 (e.g., training input, validating input, testing input) and one or more target outputs 220 that correspond to the data inputs 210. The data set also includes mapping data that maps the data inputs 210 to the target outputs 220. Data inputs 210 are also referred to as “features,” “attributes,” or information.” In some embodiments, data set generator 272 provides the data set to the training engine 182, validating engine 184, or testing engine 186, where the data set is used to train, validate, or test the machine learning model 190. Some embodiments of generating a training set are further described with respect to FIG. 4A.

In some embodiments, data set generator 272 generates the data input 210 and target output 220. In some embodiments, data inputs 210 include one or more sets of historical data.

In some embodiments, data set generator 272 generates a first data input corresponding to a first set of historical data to train, validate, or test a first machine learning model and the data set generator 272 generates a second data input corresponding to a second set of historical data to train, validate, or test a second machine learning model.

In some embodiments, the data set generator 272 discretizes (e.g., segments) one or more of the data input 210 or the target output 220 (e.g., to use in classification algorithms for regression problems). Discretization (e.g., segmentation via a sliding window) of the data input 210 or target output 220 transforms continuous values of variables into discrete values. In some embodiments, the discrete values for the data input 210 indicate discrete historical data to obtain a target output 220 (e.g., discrete historical data).

Data inputs 210 and target outputs 220 to train, validate, or test a machine learning model include information for a particular facility (e.g., for a particular substrate manufacturing facility). In some examples, historical data is for the same manufacturing facility.

In some embodiments, the information used to train the machine learning model is from specific types of manufacturing equipment 124 of the manufacturing facility having specific characteristics and allow the trained machine learning model to determine outcomes for a specific group of manufacturing equipment 124 based on input for current parameters (e.g., current data) associated with one or more components sharing characteristics of the specific group. In some embodiments, the information used to train the machine learning model is for components from two or more manufacturing facilities and allows the trained machine learning model to determine outcomes for components based on input from one manufacturing facility.

In some embodiments, subsequent to generating a data set and training, validating, or testing a machine learning model 190 using the data set, the machine learning model 190 is further trained, validated, or tested (e.g., current data) or adjusted (e.g., adjusting weights associated with input data of the machine learning model 190, such as connection weights in a neural network).

FIG. 3 is a block diagram illustrating a system 300 for generating predictive data 360 (e.g., predictive data 160 of FIG. 1), according to certain embodiments. The system 300 is used to determine predictive data 360 via a trained machine learning model (e.g., model 190 of FIG. 1) to perform additional trimming via etching of a substrate.

At block 310, the system 300 (e.g., predictive system 110 of FIG. 1) performs data partitioning (e.g., via data set generator 172 of server machine 170 of FIG. 1) of the historical data for model 190 of FIG. 1) to generate the training set 302, validation set 304, and testing set 306. In some examples, the training set is 60% of the historical data, the validation set is 20% of the historical data, and the testing set is 20% of the historical data. The system 300 generates a plurality of sets of features for each of the training set, the validation set, and the testing set. In some examples, if the historical data includes features derived from 20 operations and 100 products (e.g., products formed by the 20 operations), a first set of features is operations 1-10, a second set of features is operations 11-20, the training set is products 1-60, the validation set is products 61-80, and the testing set is products 81-100. In this example, the first set of features of the training set would be parameters from operations 1-10 for products 1-60.

In some embodiments, the historical data includes historical metrology data 344 (e.g., historical metrology data 244 of FIG. 2A, historical metrology data 144 of FIG. 1) and historical substrate thickness maps 354 (e.g., historical substrate thickness maps 254 of FIG. 2A, historical substrate thickness maps 154 of FIG. 1). In some embodiments, the historical data includes historical substrate thickness maps 354 (e.g., historical substrate thickness maps 254 of FIG. 2B, historical substrate thickness maps 154 of FIG. 1) and historical performance data 364 (e.g., historical performance data 264 of FIG. 2B, historical performance data 164 of FIG. 1).

At block 312, the system 300 performs model training (e.g., via training engine 182 of FIG. 1) using the training set 302. In some embodiments, the system 300 trains multiple models using multiple sets of features of the training set 302 (e.g., a first set of features of the training set 302, a second set of features of the training set 302, etc.). For example, system 300 trains a machine learning model to generate a first trained machine learning model using the first set of features in the training set (e.g., operations 1-10 for products 1-60) and to generate a second trained machine learning model using the second set of features in the training set (e.g., operations 11-20 for products 1-60). In some embodiments, the first trained machine learning model and the second trained machine learning model are combined to generate a third trained machine learning model (e.g., which is a better predictor than the first or the second trained machine learning model on its own in some embodiments). In some embodiments, sets of features used in comparing models overlap (e.g., first set of features being operations 1-15 and second set of features being operations 5-20). In some embodiments, hundreds of models are generated including models with various permutations of features and combinations of models.

At block 314, the system 300 performs model validation (e.g., via validation engine 184 of FIG. 1) using the validation set 304. The system 300 validates each of the trained models using a corresponding set of features of the validation set 304. For example, system 300 validates the first trained machine learning model using the first set of features in the validation set (e.g., operations 1-10 for products 61-80) and the second trained machine learning model using the second set of features in the validation set (e.g., operations 11-20 for products 61-80). In some embodiments, the system 300 validates hundreds of models (e.g., models with various permutations of features, combinations of models, etc.) generated at block 312. At block 314, the system 300 determines an accuracy of each of the one or more trained models (e.g., via model validation) and determines whether one or more of the trained models has an accuracy that meets a threshold accuracy. Responsive to determining that none of the trained models has an accuracy that meets a threshold accuracy, flow returns to block 312 where the system 300 performs model training using different sets of features of the training set. Responsive to determining that one or more of the trained models has an accuracy that meets a threshold accuracy, flow continues to block 316. The system 300 discards the trained machine learning models that have an accuracy that is below the threshold accuracy (e.g., based on the validation set).

At block 316, the system 300 performs model selection (e.g., via selection engine 185 of FIG. 1) to determine which of the one or more trained models that meet the threshold accuracy has the highest accuracy (e.g., the selected model 308, based on the validating of block 314). Responsive to determining that two or more of the trained models that meet the threshold accuracy have the same accuracy, flow returns to block 312 where the system 300 performs model training using further refined training sets corresponding to further refined sets of features for determining a trained model that has the highest accuracy.

At block 318, the system 300 performs model testing (e.g., via testing engine 186 of FIG. 1) using the testing set 306 to test the selected model 308. The system 300 tests, using the first set of features in the testing set (e.g., operations 1-10 for products 81-100), the first trained machine learning model to determine the first trained machine learning model meets a threshold accuracy (e.g., based on the first set of features of the testing set 306). Responsive to accuracy of the selected model 308 not meeting the threshold accuracy (e.g., the selected model 308 is overly fit to the training set 302 and/or validation set 304 and is not applicable to other data sets such as the testing set 306), flow continues to block 312 where the system 300 performs model training (e.g., retraining) using different training sets corresponding to different sets of features (e.g., operations). Responsive to determining that the selected model 308 has an accuracy that meets a threshold accuracy based on the testing set 306, flow continues to block 320. In at least block 312, the model learns patterns in the historical data to make predictions and in block 318, the system 300 applies the model on the remaining data (e.g., testing set 306) to test the predictions.

At block 320, system 300 uses the trained model (e.g., selected model 308) to receive current data and determines (e.g., extracts), from the trained model, predictive data 360 (e.g., predictive data 160 of FIG. 1) to perform additional thinning via etching.

In some embodiments, the current data includes current metrology data 346 (e.g., current metrology data 146 of FIG. 1) responsive to the historical data including historical metrology data 344 and historical substrate thickness maps 354. In some embodiments, the current data includes current substrate thickness map 356 (e.g., current substrate thickness map 156 of FIG. 1) responsive to the historical data including historical substrate thickness maps 354 and historical performance data 364.

In some embodiments, the current data corresponds to the same types of features in the historical data. In some embodiments, the current data corresponds to a same type of features as a subset of the types of features in historical data that is used to train the selected model 308.

In some embodiments, current data is received. In some embodiments, current data includes current metrology data 346 and current substrate thickness maps 356 (e.g., responsive to the historical data including historical metrology data 344 and historical substrate thickness maps 354). In some embodiments, the current data includes current substrate thickness map 356 and current performance data 266 (e.g., responsive to the historical data including historical substrate thickness maps 354 and historical performance data 364). In some embodiments, at least a portion of the current data is received from metrology equipment (e.g., metrology equipment 128 of FIG. 1) or via user input. In some embodiments, the model 308 is re-trained based on the current data. In some embodiments, a new model is trained based on the current data.

In some embodiments, one or more of the blocks 310-320 occur in various orders and/or with other operations not presented and described herein. In some embodiments, one or more of blocks 310-320 are not performed. For example, in some embodiments, one or more of data partitioning of block 310, model validation of block 314, model selection of block 316, and/or model testing of block 318 are not be performed.

FIGS. 4A-E are flow diagrams of methods 400A-E associated with integrated substrate thinning, according to certain embodiments. In some embodiments, methods 400A-E are performed by processing logic that includes hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiments, methods 400A-E are performed, at least in part, by predictive system 110 and/or client device 120. In some embodiments, method 400A is performed, at least in part, by predictive system 110 (e.g., server machine 170 and data set generator 172 of FIG. 1, data set generator 272 of FIGS. 2A-B). In some embodiments, predictive system 110 uses method 400A to generate a data set to at least one of train, validate, or test a machine learning model. In some embodiments, method 400B is performed by client device 120 (e.g., substrate thinning component 122). In some embodiments, method 400C is performed by server machine 180 (e.g., training engine 182, etc.). In some embodiments, method 400D is performed by predictive server 112 (e.g., predictive component 114). In some embodiments, a non-transitory storage medium stores instructions that when executed by a processing device (e.g., of predictive system 110, of server machine 180, of predictive server 112, etc.), cause the processing device to perform one or more of methods 400A-E.

For simplicity of explanation, methods 400A-E are depicted and described as a series of operations. However, operations in accordance with this disclosure can occur in various orders and/or concurrently and with other operations not presented and described herein. Furthermore, in some embodiments, not all illustrated operations are performed to implement methods 400A-E in accordance with the disclosed subject matter. In addition, those skilled in the art will understand and appreciate that methods 400A-E could alternatively be represented as a series of interrelated states via a state diagram or events.

FIG. 4A is a flow diagram of a method 400A for generating a data set for a machine learning model for generating predictive data (e.g., predictive data 160 of FIG. 1), according to certain embodiments.

Referring to FIG. 4A, in some embodiments, at block 402 the processing logic implementing method 400A initializes a training set T to an empty set.

At block 404, processing logic generates first data input (e.g., first training input, first validating input) that includes historical data (e.g., historical metrology data or historical substrate thickness maps. In some embodiments, the first data input includes a first set of features for types of historical data and a second data input includes a second set of features for types of historical data.

At block 406, processing logic generates a first target output for one or more of the data inputs (e.g., first data input). In some embodiments, the first target output is historical substrate thinning maps or historical performance data.

At block 408, processing logic optionally generates mapping data that is indicative of an input/output mapping. The input/output mapping (or mapping data) refers to the data input (e.g., one or more of the data inputs described herein), the target output for the data input (e.g., where the target output identifies historical performance data 164), and an association between the data input(s) and the target output.

At block 410, processing logic adds the mapping data generated at block 408 to data set T.

At block 412, processing logic branches based on whether data set T is sufficient for at least one of training, validating, and/or testing machine learning model 190 (e.g., uncertainty of the trained machine learning model meets a threshold uncertainty). If so, execution proceeds to block 414, otherwise, execution continues back to block 404. It should be noted that in some embodiments, the sufficiency of data set T is determined based simply on the number of input/output mappings in the data set, while in some other implementations, the sufficiency of data set T is determined based on one or more other criteria (e.g., a measure of diversity of the data examples, accuracy, etc.) in addition to, or instead of, the number of input/output mappings.

At block 414, processing logic provides data set T (e.g., to server machine 180) to train, validate, and/or test machine learning model 190. In some embodiments, data set T is a training set and is provided to training engine 182 of server machine 180 to perform the training. In some embodiments, data set T is a validation set and is provided to validation engine 184 of server machine 180 to perform the validating. In some embodiments, data set T is a testing set and is provided to testing engine 186 of server machine 180 to perform the testing. In the case of a neural network, for example, input values of a given input/output mapping (e.g., numerical values associated with data inputs 210) are input to the neural network, and output values (e.g., numerical values associated with target outputs 220) of the input/output mapping are stored in the output nodes of the neural network. The connection weights in the neural network are then adjusted in accordance with a learning algorithm (e.g., back propagation, etc.), and the procedure is repeated for the other input/output mappings in data set T.

After block 414, machine learning model (e.g., machine learning model 190) can be at least one of trained using training engine 182 of server machine 180, validated using validating engine 184 of server machine 180, or tested using testing engine 186 of server machine 180. The trained machine learning model is implemented by predictive component 114 (of predictive server 112) to generate predictive data (e.g., predictive data 160) for integrated substrate thinning.

FIG. 4B is a method 400B associated with integrated substrate thinning, according to certain embodiments.

At block 420 of method 400B, the processing logic identifies a substrate thickness map of a substrate thinned via one or more chemical mechanical planarization (CMP) operations.

In some embodiments, the identifying of the substrate thickness map includes receiving metrology data in situ (e.g., in-situ spectral reflectometry) during thinning of the substrate via the one or more CMP operations and generating, based on the metrology data, the substrate thickness map of the substrate. In some embodiments, the in-situ metrology from the CMP tool may be in-situ spectral reflectometry.

In some embodiments, the substrate thickness map is based on output of a trained machine learning model (e.g., see FIGS. 4C-D).

At block 422, the processing logic causes, based on the substrate thickness map, additional thinning of the substrate via etching of the substrate. In some embodiments, at block 422, the processing logic causes the recipe (e.g., to perform additional thinning via etching) to be dynamically adjusted based on the substrate thickness map.

In some embodiments, block 422 (causing of the additional thinning) includes determining, based on the substrate thickness map, temperature offsets and causing, based on the temperature offsets, microzone heating of the substrate during etching of the substrate. In some embodiments, block 422 (the causing of the additional thinning) includes causing, based on the substrate thickness map, adjustment of height of a process kit ring associated with the etching of the substrate.

In some embodiments, the processing logic receives the substrate thickness map that has been encrypted, where the causing of the additional thinning includes providing the substrate thickness map that has been encrypted to a server device.

In some embodiments, block 422 is based on a trained machine learning model (e.g., see FIGS. 4C-D).

In some embodiments, the substrate having a first planarization value responsive to the CMP operations, the substrate having a second planarization value responsive to the additional thinning, the second planarization value being more planar than the first planarization value.

In some embodiments, the substrate includes a first face and a second face opposite the first face, the first face being bonded to a corresponding face of an additional substrate, the one or more CMP operations and the etching to remove at least a portion of the second face to reduce thickness of the substrate.

In some embodiments, the substrate thickness map is a silicon thickness map. In some embodiments, the CMP operations and the etching are associated with backside power delivery network (BSPDN).

In some embodiments, integrated substrate thinning (e.g., an integrated approach to silicon (Si) thinning) is performing CMP operations and then additional thinning via etching. The additional thinning via etching may be based on a substrate thickness map generated based on metrology data generated in situ (e.g., in situ metrology data) during the CMP operations or after the CMP operations). In some embodiments, the integrated substrate thinning is Si thinning with microzone etch (e.g., micro zoom etch) plus CMP operations for a BSPDN solution. In some embodiments, Si thinning is in a total thickness variation (TTV) module with microzone etch plus CMP operations (e.g., for BSPDN solution, BSPDN integration).

Conventionally for BSPDN, there may be a radial edge thickness drop due to the grind operations (e.g., substrate edge thickness is thinner than other portions of the substrate). In some embodiments, at block 422 (e.g., during the microzone etch), the substrate edge etch rate (ER) can be changed with an adjustment in height of the process kit ring (e.g., reduced ER by using higher process kit ring height). Due to lower ion flux at substrate edge (e.g., shading), a higher depth at substrate edge created from grind process can be corrected. In some embodiments, the process kit ring (e.g., edge ring) may be located in the processing chamber around the substrate and on the electrostatic chuck.

Conventionally, etching (e.g., correcting planarization via etching) may be base don an incoming thickness map and without in-situ tuning which may lead to over-correction. This may cause high asymmetry.

The present disclosure may provide greater than 10 degrees Celsius adjustment on the microzone chuck. The present disclosure may allow processing with greater ER sensitivity to temperature. The present disclosure may provide dynamic temperature control through the etch. The present disclosure may have higher temperature delta and/or higher amount of temperature dependent Si etch rate.

The present disclosure may include receiving post-CMP Si thickness data (e.g., substrate thickness map of a substrate thinned via CMP operations), computing offset temperatures based on the substrate thickness map, and controlling the electrostatic chuck based on the offset temperatures.

In some embodiments, the processing logic causes the additional thinning based on the substrate thickness map, substrate temperature data, and/or target temperature profile (e.g., x- and y-coordinates with target temperature). The processing logic may output of microzone heater power data to be used by the heater controller to control the microzone heaters. In some embodiments, temperature setpoints of microzone heaters are determined based on the substrate thickness map.

The present disclosure may compensate processing chamber electrostatic chuck and plasma non-uniformity better than conventional solutions.

FIG. 4C is a method 400C for training a machine learning model (e.g., model 190 of FIG. 1) for determining predictive data (e.g., predictive data 160 of FIG. 1) for integrated substrate thinning.

Referring to FIG. 4C, at block 440 of method 400C, the processing logic identifies historical data (e.g., historical metrology data and historical substrate thickness maps, historical substrate thickness maps and historical performance data).

At block 442, the processing logic trains a machine learning model using data input and target output to generate a trained machine learning model. In some embodiments, the data input is historical metrology data and the target output is historical substrate thickness maps. In some embodiments, the data input is historical substrate thickness maps and the target output is historical performance data.

One or more operations of FIG. 4B may be by using the trained machine learning model of FIG. 4C. In some embodiments, the trained machine learning model is a neural network.

In some embodiments, the processing logic identifies historical metrology data (e.g., in situ CMP metrology data) of historical substrates associated with performing historical CMP operations, identifies historical substrate thickness maps associated with the historical substrates thinned via the historical CMP operations, and trains a machine learning model using input comprising the historical metrology data and target output comprising the historical substrate thickness maps to generate a trained machine learning model configured provide output associated with the substrate thickness map.

In some embodiments, the processing logic identifies historical substrate thickness maps associated with historical substrates thinned via historical CMP operations, identifies historical performance data (e.g., in situ or post-etching metrology data) associated with historical additional thinning of the historical substrates, and trains a machine learning model using input comprising the historical substrate thickness maps and target output comprising the historical performance data to generate a trained machine learning model configured provide output associated with the causing of the additional thinning.

FIG. 4D is a method 400D for using a trained machine learning model (e.g., model 190 of FIG. 1) for integrated substrate thinning.

Referring to FIG. 4D, at block 460 of method 400D, the processing logic identifies current data (e.g., current metrology data or current substrate thickness map).

At block 462, the processing logic provides the current data as data input to a trained machine learning model (e.g., trained via block 444 of FIG. 4C).

At block 464, the processing logic receives, from the trained machine learning model, output associated with predictive data.

At block 466, the processing logic causes, based on the predictive data, additional thinning of a substrate via thinning.

In some embodiments, the processing logic identifies metrology data (e.g., in situ CMP metrology data) associated with the substrate thinned via the one or more CMP operations, provides the metrology data as input to a trained machine learning model, and receives, from the trained machine learning model, output. The identifying of the substrate thickness map is associated with the output.

In some embodiments, the processing logic provides the substrate thickness map as input to a trained machine learning model and receives, from the trained machine learning model, output, wherein the causing of the additional thinning is based on the output. Temperature offsets for controlling of the microzone heaters and/or process kit ring height adjustment may be determined based on the output.

FIG. 4E illustrates a method of integrated substrate thinning, according to certain embodiments. Three-dimensional (3D) packaging technologies (e.g., wafer-on-wafer technologies) may use processing and handling of substrates (e.g., silicon wafers) that have been thinned (e.g., to less than 50 microns). BSPDN may be one such application where the backside of a bonded device substrate is thinned before a direct backside source/drain connection is established. The thinning may be with front end of line (FEOL) (e.g., first portion of substrate processing where individual devices are patterned in the substrate) plus back end of line (BEOL) (e.g., subsequent deposition of metal interconnect layers). Thinned substrates (e.g., thinned Si wafers) may have a final total Si thickness variation that meet a threshold value (e.g., less than or greater than 10 nanometers) due to limited process windows of downstream operations like lithography when doing the integration on the backside of the wafer.

At block 470, processing logic causes a device structure 482 to be produced. The device structure 482 may include a device Si substrate 490, device structures 492 on the device Si substrate 490, and bonding dielectric 494A on the device structures 492.

At block 472, processing logic causes a carrier structure 484 to be produced. The carrier structure 484 may include a carrier Si substrate 496 and bonding dielectric 494B on the carrier Si substrate 496.

At block 474, processing logic causes bonding of the device structure 482 and the carrier structure 484 (e.g., face to face, dielectric to dielectric) to form a substrate structure 486. The device structure 482 may be horizontally flipped and the dielectric 494A of device structure 482 may be bonded to dielectric 494B of carrier structure 484 form substrate structure 486. In some embodiments, edge trimming is performed prior block 476.

At block 476, processing logic causes device Si substrate 490 of substrate structure 486 to be thinned via grinding (e.g., by grinding tool 125 of FIG. 1). The grinding may be tuned to minimize generated asymmetry and edge roll off (e.g., center to edge thickness variation may be corrected by CMP, the grind process may focus on minimizing mid-frequency asymmetric variation since short-range thickness variation can be planarized by CMP and longer scale asymmetric variation can be fixed by microzone etch).

In some embodiments, silicon wafer grind produces variable incoming non-uniformity from substrate to substrate. In some embodiments, post-grind substrates may have variable incoming silicon thickness profiles and/or thicknesses. CMP operations may have little control of removal asymmetry and exact nature of generated asymmetry may not be predicted.

At block 478, processing logic causes device Si substrate 490 of substrate structure 486 to be further thinned via one or more CMP operations (e.g., by CMP tool 127 of FIG. 1). Metrology data of the of substrate structure 486 is generated in situ (e.g., during the CMP operations) or after the CMP operations (e.g., via metrology equipment 128 of FIG. 1). A substrate thickness map is generated based on the metrology data.

The CMP operations of block 478 may be performed after the grind operation of block 476. The CMP operations of block 478 may be used to minimize radial variations via automation using a multi-zone polish head with in situ radial profile control. The pad (e.g., multi-zone polish head) may be selected based on expected extreme edge removal. CMP removal in this operation may leave enough silicon for microzone etch to correct the asymmetric variation that is expected to remain. The removal in this operation may be minimized to avoid generating additional edge asymmetry but should be large enough to feasibly correct center-to-edge non-uniformity and to planarize short-range thickness variation. Pad selection may be tuned (e.g., planarization length changes) to appropriately planarize grind-related short range thickness variation (e.g., grind marks) while minimizing asymmetry generation from substrate shape variation.

The processing logic may collect in-situ thickness information for in-situ control during the polish process (e.g., CMP operation). Processing logic may collect thickness data during the post-polish rinse operations. This data may have significantly better spatial resolution than a substrate map that can be measured on a conventional in-line or onboard metrology system. If the substrate is appropriately notch-aligned prior to the polish and platen/head indexing is done before the start of the polish, the data may be repeatable x-y coordinates and may be used to produce a post-CMP substrate thickness map that characterizes asymmetry. The substrate thickness map may be used to tune microzone etch without a pre-etch metrology operation.

In some embodiments, the CMP operations can remove at least a portion of radial non-uniformity during bulk silicon polish. Subsequent to the CMP operations, there may remain asymmetric nonuniformity in silicon thickness that results from the grind process. The asymmetry may be substrate dependent. In some embodiments, an adaptive process of block 480 is used to correct asymmetry before relying on a final CMP operation to stop on the isolation oxide and further minimize thickness variation. Reducing thickness variation via block 480 prior to the final CMP operation reduces the overpolish used to remove any silicon residue on the isolation and recues the resultant dishing.

At block 480, processing logic causes device Si substrate 490 of substrate structure 486 to be further thinned via etching (e.g., microzone etching, via etching tool 129 of FIG. 1) based on the substrate thickness map. In some embodiments, processing logic determines temperature offsets based on the substrate thickness map and controls the microzone temperatures based on the temperature offsets during the etching. In some embodiments, processing logic adjusts heights of the process kit ring (e.g., edge ring) based on the substrate thickness map during the etching.

The microzone etch of block 480 may reduce asymmetric variation of the substrate (e.g., variation at any given single substrate radius). This allows the final CMP operation to expose shallow trench isolation (STI) across the substrate without using significant overpolish of areas on the substrate that have thinner silicon overburden. The microzone etch of block 480 may substantially not degrade center-to-edge radial uniformity. The processing logic may automatically determine an appropriate set of microzone recipe settings based on the substrate thickness map of the incoming substrate since the incoming asymmetry is not being actively controlled by the grind or CMP operations. The microzone etch may leave a minimal overburden for STI stop CMP to minimize impacts of process variation in that operation.

In some embodiments, metrology for microzone etch may be used to characterize an incoming substrate profile and can be used to update a model that characterizes the microzone etch process response to microzone heater setpoints. The metrology may be dense enough to characterize thickness over affectable regions of the response. A medium spot reflectometer with a reasonable sampling rate may be able to acquire sufficient data.

In some embodiments, method 400E is performed to provide backside power delivery (e.g., to the device Si substrate 490 subsequent to the thinning operations) to the substrate structure 486. In some embodiments, method 400E thins the device Si substrate 490 from several hundred-micron thickness down to a few microns that is substantially uniform (e.g., substantially planar).

In some embodiments, at block 480, the performing of the additional thinning via etching based on the substrate thickness map causes: adjustment of the height of the process kit ring (e.g., adjusting edge ring height) to correct far edge radial non-uniformity (e.g., cause the device Si substrate 490 to be substantially planar at the edges of the upper surface, correct center to edge variation); and causes microzone temperature adjustments to correct for asymmetric non-uniformity (e.g., cause the device Si substrate 490 to be substantially planar across the upper surface).

In some embodiments, at block 481, processing logic performs an additional CMP operation of device Si substrate 490 of substrate structure 486 after the additional thinning via etching (e.g., microzone etching). In some embodiments, the additional CMP operation may perform further thinning of device Si substrate 490 of substrate structure 486 based on metrology data collected during or after the etching.

Although method 400E illustrates performing thinning operations of the device Si substrate 490, one or more operations of method 400E may be applied to thinning operations of other materials and/or substrates (e.g., thinning an oxide layer).

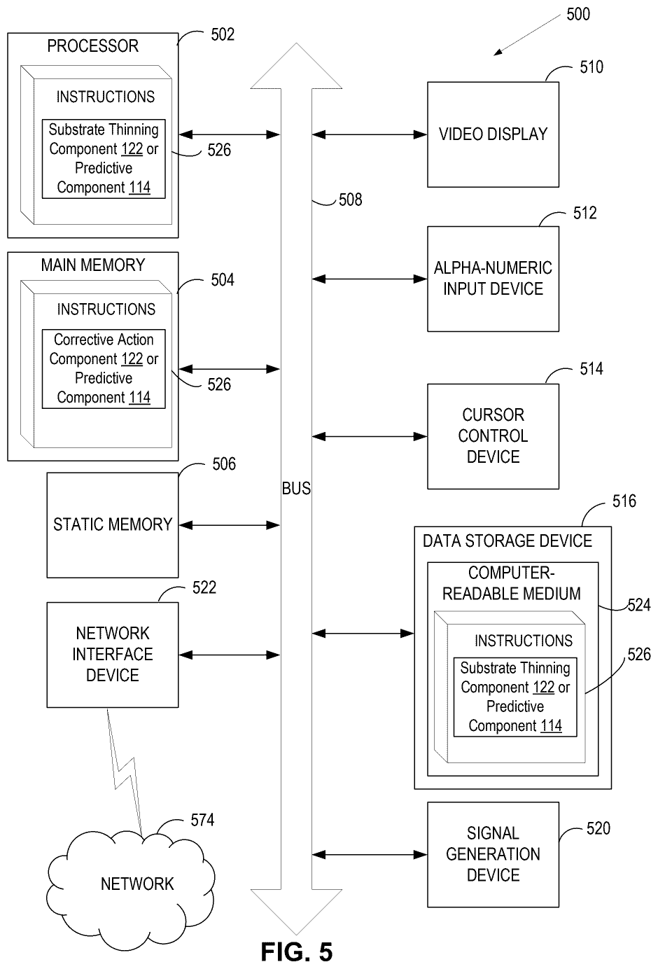

FIG. 5 is a block diagram illustrating a computer system 500, according to certain embodiments. In some embodiments, the computer system 500 is one or more of client device 120, predictive system 110, server machine 170, server machine 180, or predictive server 112.

In some embodiments, computer system 500 is connected (e.g., via a network, such as a Local Area Network (LAN), an intranet, an extranet, or the Internet) to other computer systems. In some embodiments, computer system 500 operates in the capacity of a server or a client computer in a client-server environment, or as a peer computer in a peer-to-peer or distributed network environment. In some embodiments, computer system 500 is provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 500 includes a processing device 502, a volatile memory 504 (e.g., Random Access Memory (RAM)), a non-volatile memory 506 (e.g., Read-Only Memory (ROM) or Electrically Erasable Programmable ROM (EEPROM)), and a data storage device 516, which communicate with each other via a bus 508.

In some embodiments, processing device 502 is provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

In some embodiments, computer system 500 further includes a network interface device 522 (e.g., coupled to network 574). In some embodiments, computer system 500 also includes a video display unit 510 (e.g., a liquid crystal display (LCD)), an alphanumeric input device 512 (e.g., a keyboard), a cursor control device 514 (e.g., a mouse), and a signal generation device 520.

In some implementations, data storage device 516 includes a non-transitory computer-readable storage medium 524 on which store instructions 526 encoding any one or more of the methods or functions described herein, including instructions encoding components of FIG. 1 (e.g., substrate thinning component 122, predictive component 114, etc.) and for implementing methods described herein.

In some embodiments, instructions 526 also reside, completely or partially, within volatile memory 504 and/or within processing device 502 during execution thereof by computer system 500, hence, in some embodiments, volatile memory 504 and processing device 502 also constitute machine-readable storage media.

While computer-readable storage medium 524 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

In some embodiments, the methods, components, and features described herein are implemented by discrete hardware components or are integrated in the functionality of other hardware components such as application-specific integrated circuits (ASICs), field programmable gate arrays (FPGAs), digital signal processors (DSPs), or similar devices. In some embodiments, the methods, components, and features are implemented by firmware modules or functional circuitry within hardware devices. In some embodiments, the methods, components, and features are implemented in any combination of hardware devices and computer program components, or in computer programs.

Unless specifically stated otherwise, terms such as “identifying,” “causing,” “thinning,” “additional thinning,” “receiving,” “generating,” “determining,” “providing,” “training,” “obtaining,” “outputting,” “predicting,” “updating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. In some embodiments, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein or includes a general-purpose computer system selectively programmed by a computer program stored in the computer system. Such a computer program is stored in a computer-readable tangible storage medium.

The methods and illustrative examples described herein are not inherently related to any particular computer or other apparatus. In some embodiments, various general-purpose systems are used in accordance with the teachings described herein. In some embodiments, a more specialized apparatus is constructed to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method comprising:
identifying a substrate thickness map of a substrate thinned via one or more chemical mechanical planarization (CMP) operations; and
causing, based on the substrate thickness map, additional thinning of the substrate via etching of the substrate.

2. The method of claim 1, wherein the identifying of the substrate thickness map comprises:
receiving metrology data in situ during thinning of the substrate via the one or more CMP operations; and
generating, based on the metrology data, the substrate thickness map of the substrate.

3. The method of claim 1, wherein the causing of the additional thinning comprises:
determining, based on the substrate thickness map, temperature offsets; and
causing, based on the temperature offsets, microzone heating of the substrate during etching of the substrate.

4. The method of claim 1, wherein the causing of the additional thinning comprises causing, based on the substrate thickness map, adjustment of height of a process kit ring associated with the etching of the substrate.

5. The method of claim 1, wherein the substrate comprises a first face and a second face opposite the first face, the first face being bonded to a corresponding face of an additional substrate, the one or more CMP operations and the etching to remove at least a portion of the second face to reduce thickness of the substrate.

6. The method of claim 1 further comprising receiving the substrate thickness map that has been encrypted, wherein the causing of the additional thinning comprises providing the substrate thickness map that has been encrypted to a server device.

7. The method of claim 1, the substrate having a first planarization value responsive to the CMP operations, the substrate having a second planarization value responsive to the additional thinning, the second planarization value being more planar than the first planarization value.

8. The method of claim 1, wherein at least one of:
the substrate thickness map is a silicon thickness map; or
the CMP operations and the etching are associated with backside power delivery network (BSPDN).

9. The method of claim 1 further comprising:
identifying metrology data associated with the substrate thinned via the one or more CMP operations;
providing the metrology data as input to a trained machine learning model; and
receiving, from the trained machine learning model, output, wherein the identifying of the substrate thickness map is associated with the output.

10. The method of claim 1 further comprising:
identifying historical metrology data of historical substrates associated with performing historical CMP operations;
identifying historical substrate thickness maps associated with the historical substrates thinned via the historical CMP operations; and
training a machine learning model using input comprising the historical metrology data and target output comprising the historical substrate thickness maps to generate a trained machine learning model configured provide output associated with the substrate thickness map.

11. The method of claim 1 further comprising:
providing the substrate thickness map as input to a trained machine learning model; and
receiving, from the trained machine learning model, output, wherein the causing of the additional thinning is based on the output.

12. The method of claim 1 further comprising:
identifying historical substrate thickness maps associated with historical substrates thinned via historical CMP operations;
identifying historical performance data associated with historical additional thinning of the historical substrates; and
training a machine learning model using input comprising the historical substrate thickness maps and target output comprising the historical performance data to generate a trained machine learning model configured provide output associated with the causing of the additional thinning.

13. A non-transitory machine-readable storage medium storing instructions which, when executed cause a processing device to perform operations comprising:
identifying a substrate thickness map of a substrate thinned via one or more chemical mechanical planarization (CMP) operations; and
causing, based on the substrate thickness map, additional thinning of the substrate via etching of the substrate.

14. The non-transitory machine-readable storage medium of claim 13, wherein the identifying of the substrate thickness map comprises:
receiving metrology data in situ during thinning of the substrate via the one or more CMP operations; and
generating, based on the metrology data, the substrate thickness map of the substrate.

15. The non-transitory machine-readable storage medium of claim 13, wherein the causing of the additional thinning comprises:
determining, based on the substrate thickness map, temperature offsets; and
causing, based on the temperature offsets, microzone heating of the substrate during etching of the substrate.

16. The non-transitory machine-readable storage medium of claim 13, wherein the causing of the additional thinning comprises causing, based on the substrate thickness map, adjustment of height of a process kit ring associated with the etching of the substrate.

17. A system comprising:
memory; and
a processing device coupled to the memory, the processing device to:
identify a substrate thickness map of a substrate thinned via one or more chemical mechanical planarization (CMP) operations; and
cause, based on the substrate thickness map, additional thinning of the substrate via etching of the substrate.

18. The system of claim 17, wherein to identify the substrate thickness map, the processing device is to:
receive metrology data in situ during thinning of the substrate via the one or more CMP operations; and
generate, based on the metrology data, the substrate thickness map of the substrate.

19. The system of claim 17, wherein to cause the additional thinning, the processing device is to:
determine, based on the substrate thickness map, temperature offsets; and
cause, based on the temperature offsets, microzone heating of the substrate during etching of the substrate.

20. The system of claim 17, wherein to cause the additional thinning, the processing device is to cause, based on the substrate thickness map, adjustment of height of a process kit ring associated with the etching of the substrate.
